(19) United States
(12) Patent Application Publication
(10) Pub. No.: US 2023/0382717 A1
(43) Pub. Date: Nov. 30, 2023

(54) MEMS SENSOR AND MEMS SENSOR MANUFACTURING METHOD

(71) Applicant: ROHM CO., LTD., Kyoto (JP)

(72) Inventor: Martin Wilfried HELLER, Kyoto (JP)

(73) Assignee: ROHM CO., LTD., Kyoto (JP)

(21) Appl. No.: 18/448,600

(22) Filed: Aug. 11, 2023

Related U.S. Application Data
(63) Continuation of application No. PCT/JP2022/003106, filed on Jan. 27, 2022.

(30) Foreign Application Priority Data
Feb. 26, 2021 (JP) 2021-031015

(51) Int. Cl. B81B 3/00; B81C 1/00; G01P 15/125

(52) U.S. Cl. CPC B81B 3/0051; B81C 1/00341; G01P 15/125; B81B 2201/0235; B81B 2203/0118; B81B 2203/0315; B81B 2203/04; B81C 2201/0109; B81C 2201/0132

(57) ABSTRACT

A MEMS sensor includes a semiconductor chip that has a first principal surface and a second principal surface and that has a cavity, a frame portion that forms a bottom portion and a side portion of the cavity, and a movable portion that is formed on the side of the first principal surface and that is supported by the frame portion in a floating state with respect to the cavity, and, in the MEMS sensor, the frame portion has a stepped surface formed at a height position between the bottom portion of the cavity and the first principal surface, and the movable portion includes a main body portion facing the cavity in a first direction and an extension portion that extends from the main body portion toward an upper region of the stepped surface in a second direction and that faces the stepped surface in the first direction.

### CROSS REFERENCE TO RELATED APPLICATIONS

The present application is a continuation application of PCT Application No. PCT/JP2022/003106, filed on Jan. 27, 2022, which corresponds to Japanese Patent Application No. 2021-31015 filed with the Japan Patent Office on Feb. 26, 2021, and the entire disclosure of the application is incorporated herein by reference.

### BACKGROUND

### 1. Technical Field

The present disclosure relates to a MEMS sensor and a method for manufacturing the MEMS sensor.

### 2. Description of the Related Art

For example, U.S. Pat. No. 6,792,804 discloses an acceleration sensor. The acceleration sensor includes, for example, a fixed portion consisting of two layers, i.e., a Si electrode and a metal electrode stacked together in this order with an insulation layer therebetween, and a movable portion that is the same in shape as the Si electrode of the fixed portion and that consists of a single layer of a Si electrode completely facing the Si electrode of the fixed portion in a reference posture. The acceleration sensor detects acceleration in the direction of a Z axis by detecting an amount of change in electrostatic capacity between the Si electrode of the movable portion vibrating upwardly and downwardly by the action of acceleration and the Si electrode of the fixed portion.

### BRIEF DESCRIPTION OF DRAWINGS

FIG. 1 is a schematic plan view of a MEMS sensor according to a preferred embodiment of the present disclosure.

FIG. 2 is a cross-sectional view taken along line II-II of FIG. 1.

FIG. 3 is a perspective view showing a main portion of the MEMS sensor of FIG. 1.

FIG. 4 is an enlarged view of a part surrounded by alternate long and two short dashes line IV of FIG. 1.

FIG. 5 is a cross-sectional view taken along line V-V of FIG. 4.

FIG. 6 is a cross-sectional view taken along line VI-VI of FIG. 4.

FIG. 7A and FIG. 7B are views each of which shows a part of a process for manufacturing the MEMS sensor.

FIG. 8A and FIG. 8B are views showing a step subsequent to that of FIG. 7A and a step subsequent to that of FIG. 7B, respectively.

FIG. 9A and FIG. 9B are views showing a step subsequent to that of FIG. 8A and a step subsequent to that of FIG. 8B, respectively.

FIG. 10A and FIG. 10B are views showing a step subsequent to that of FIG. 9A and a step subsequent to that of FIG. 9B, respectively.

FIG. 11A and FIG. 11B are views showing a step subsequent to that of FIG. 10A and a step subsequent to that of FIG. respectively.

### DESCRIPTION OF EMBODIMENTS

First, preferred embodiments of the present disclosure will be listed and described.

A MEMS sensor according to a preferred embodiment of the present disclosure includes a semiconductor chip that has a first principal surface and a second principal surface on a side opposite to the first principal surface and that has a cavity formed in an inside of the semiconductor chip, a frame portion that is formed on the side of the second principal surface of the semiconductor chip and that forms a bottom portion and a side portion of the cavity, and a movable portion that is formed on the side of the first principal surface of the semiconductor chip and that is supported by the frame portion in a floating state with respect to the cavity, and, in the MEMS sensor, the frame portion has a stepped surface formed at a height position between the bottom portion of the cavity and the first principal surface, and the movable portion includes a main body portion facing the cavity in a first direction that is a thickness direction of the semiconductor chip and an extension portion that extends from the main body portion toward an upper region of the stepped surface in a second direction perpendicular to the first direction and that faces the stepped surface in the first direction.

In the MEMS sensor according to the preferred embodiment of the present disclosure, the frame portion may have a concave portion that has a bottom surface formed of the stepped surface and a side surface extending from the bottom surface toward the first principal surface and that is open toward the side of the main body portion of the movable portion, and the extension portion may include a first projection portion that is housed in the concave portion while selectively protruding from the main body portion and that has a side surface facing the side surface of the concave portion at a distance from the side surface of the concave portion.

In the MEMS sensor according to the preferred embodiment of the present disclosure, the main body portion of the movable portion may include a loss portion formed by partially losing the main body portion, and the frame portion may include a second projection portion that is housed in the loss portion while selectively protruding toward the loss portion and that has a side surface facing a side surface of the loss portion at a distance from the side surface of the loss portion.

In the MEMS sensor according to the preferred embodiment of the present disclosure, the extension portion of the movable portion may be formed thinner than the main body portion of the movable portion.

In the MEMS sensor according to the preferred embodiment of the present disclosure, the semiconductor chip may include a first layer made of a first semiconductor material and a second layer that is formed on the first layer and that is made of a second semiconductor material, and the stepped surface of the frame portion may be formed by an upper surface of the first layer that is continuous with a boundary surface between the first layer and the second layer, and the movable portion may be formed by the second layer, and the extension portion of the movable portion may be formed thinner than the main body portion of the movable portion, and may face the stepped surface at a distance from the stepped surface.

In the MEMS sensor according to the preferred embodiment of the present disclosure, the first semiconductor material and the second semiconductor material may be materials that are the same as each other.

The MEMS sensor according to the preferred embodiment of the present disclosure may further include a fixed electrode having a cantilever structure formed integrally with the frame portion, and, in the MEMS sensor, the movable portion may include a movable electrode that has a cantilever structure extending from the main body portion in parallel with the fixed electrode and that is displaced with respect to the fixed electrode.

The MEMS sensor according to the preferred embodiment of the present disclosure may include an acceleration sensor.

A method for manufacturing a MEMS sensor according to a preferred embodiment of the present disclosure includes a step of selectively forming a first trench in a first layer made of a first semiconductor material, a step of selectively forming a sacrifice layer on the first layer, the sacrifice layer integrally including a first part that is made of a material having an etching selection ratio with respect to the first semiconductor material and that is buried in the first trench and a second part led out from the first part along a principal surface of the first layer, a step of forming a second layer made of a second semiconductor material on the first layer so as to cover the sacrifice layer, a step of forming a second trench in the second layer by selectively removing the second layer so that the first part of the sacrifice layer is covered with the second layer and so that the second part of the sacrifice layer is exposed from the second layer, a step of forming a third trench that reaches the first layer from a principal surface of the second layer through the second layer, a step of forming a cavity reaching the first trench in the first layer by isotropically etching the first layer through the third trench, and a step of removing the sacrifice layer through the second trench.

In the method for manufacturing a MEMS sensor according to the preferred embodiment of the present disclosure, the first semiconductor material may be Si, and the sacrifice layer may be SiO₂.

In the method for manufacturing a MEMS sensor according to the preferred embodiment of the present disclosure, the step of forming the second trench and the step of forming the third trench may be performed by a same etching step.

Next, the preferred embodiments of the present disclosure will be described in detail with reference to the accompanying drawings. In the following detailed description, a plurality of components each of which has a name to which an ordinal number has been assigned exist, and yet this ordinal number and an ordinal number of a component recited in the appended claims do not necessarily coincide with each other.

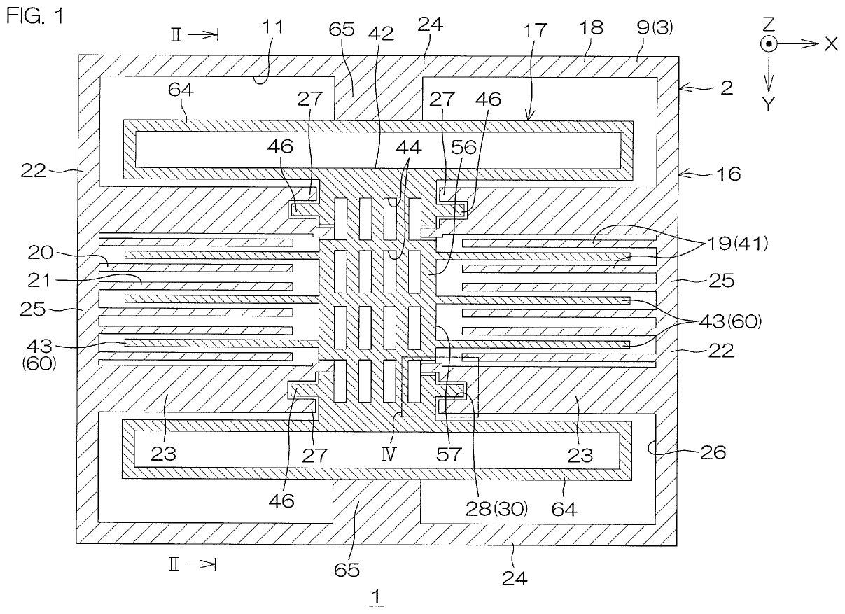

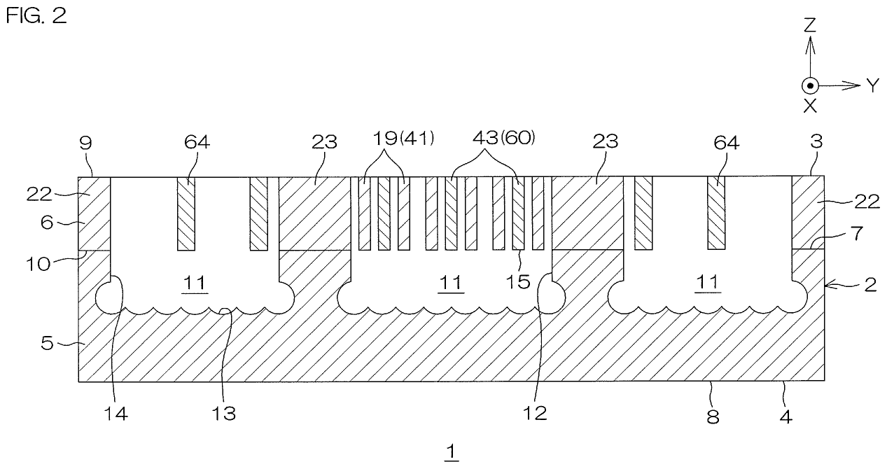

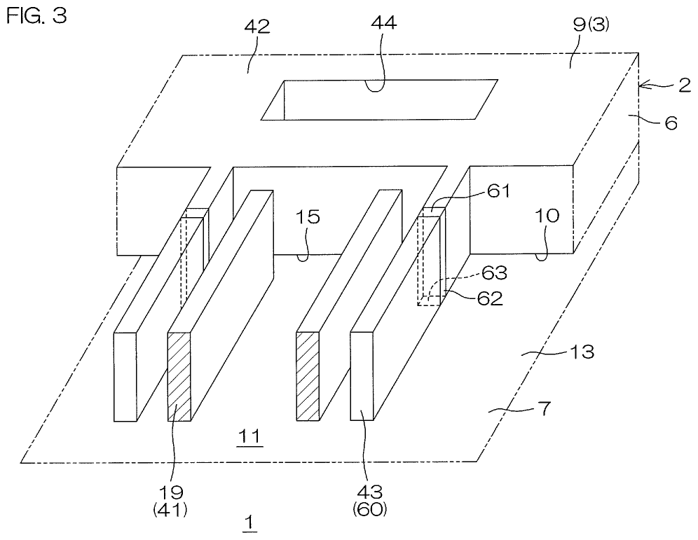

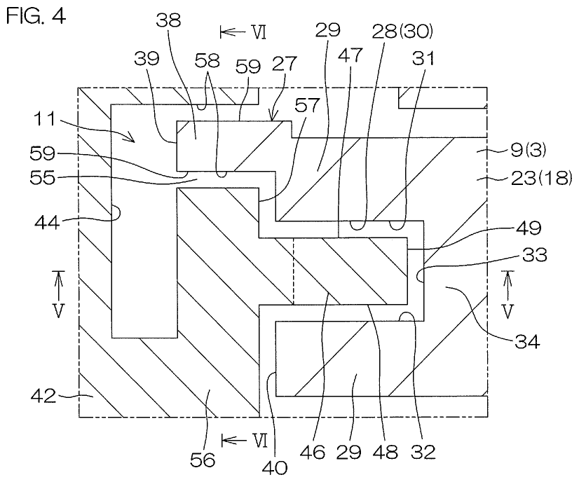

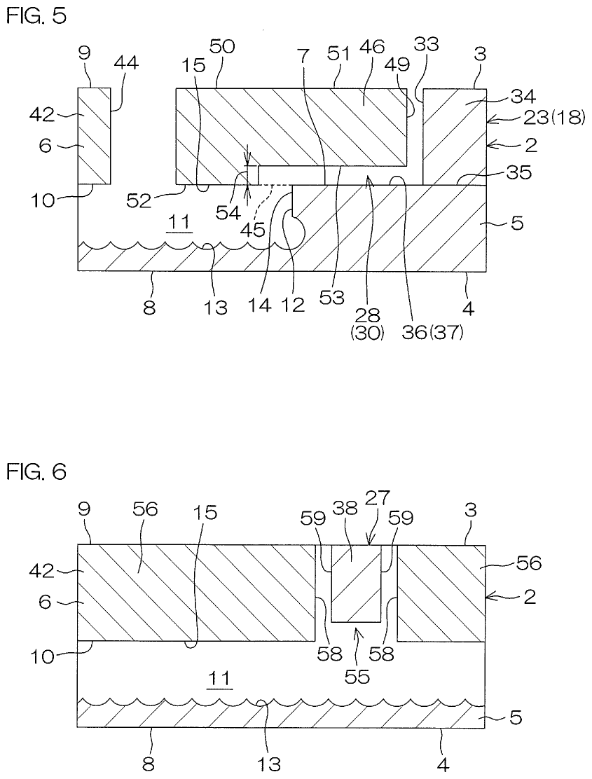

FIG. 1 is a schematic plan view of a MEMS sensor 1 according to a preferred embodiment of the present disclosure. FIG. 2 is a cross-sectional view taken along line II-II of FIG. 1. FIG. 3 is a perspective view showing a main portion of the MEMS sensor 1 of FIG. 1. FIG. 4 is an enlarged view of a part surrounded by alternate long and two short dashes line IV of FIG. 1. FIG. 5 is a cross-sectional view taken along line V-V of FIG. 4. FIG. 6 is a cross-sectional view taken along line VI-VI of FIG. 4.

In this preferred embodiment, the MEMS sensor 1 may be an acceleration sensor. The MEMS sensor 1 detects acceleration acting in, for example, a second direction Y among first, second, and third directions X, Y, and Z.

The MEMS sensor 1 includes a semiconductor chip 2. The semiconductor chip 2 forms an external shape of the MEMS sensor 1. For example, the semiconductor chip 2 is a structure in which a single-crystal semiconductor material is formed in a chip shape (rectangular parallelepiped shape). The semiconductor chip 2 is made of a semiconductor material such as Si. The semiconductor chip 2 has a first principal surface 3 and a second principal surface 4 on the side opposite to the first principal surface 3. The first principal surface 3 may be an upper surface of the semiconductor chip 2, and the second principal surface 4 may be a lower surface of the semiconductor chip 2. The first principal surface 3 may be a processing surface of the semiconductor chip 2 on which a MEMS structure is formed, and the second principal surface 4 may be a non-processing surface in contrast to the processing surface.

In this preferred embodiment, the semiconductor chip 2 includes a first layer 5 and a second layer 6 on the first layer 5. In this preferred embodiment, the first layer 5 may be a semiconductor substrate (for example, Si substrate). The thickness of the first layer 5 may be, for example, not less than 10 μm and not more than 725 μm. The first layer 5 has a first principal surface 7 and a second principal surface 8 on the side opposite to the first principal surface 7. The second principal surface 8 of the first layer 5 may be the second principal surface 4 of the semiconductor chip 2. Additionally, the first principal surface 7 and the second principal surface 8 of the first layer 5 may be referred to as an upper surface and a lower surface of the first layer 5, respectively.

The second layer 6 is a layer in which a mechanical structure of the MEMS sensor 1 is formed. In this preferred embodiment, the second layer 6 may be an epitaxial layer (for example, Si epitaxial layer). The thickness of the second layer 6 may be smaller than that of the first layer 5. The thickness of the second layer 6 may be, for example, not less than 1 μm and not more than 150 μm. The second layer 6 has a first principal surface 9 and a second principal surface 10 on the side opposite to the first principal surface 9. The first principal surface 9 of the second layer 6 may be the first principal surface 3 of the semiconductor chip 2. Additionally, the first principal surface 9 and the second principal surface 10 of the second layer 6 may be referred to as an upper surface and a lower surface of the second layer 6, respectively.

A cavity 11 is formed between the first layer 5 and the second layer 6. The cavity 11 is formed by a concave portion 12 formed in the first layer 5, and an opening end of the concave portion 12 is covered with the second layer 6. The cavity 11 has a bottom surface 13 and a side surface 14 that are formed by the first layer 5 and an upper surface 15 that is formed by the second principal surface 10 of the second layer 6. The depth of the cavity 11 (depth from the first principal surface 7 of the first layer 5) may be, for example, not less than 1 μm and not more than 50 μm. The bottom surface 13 of the cavity 11 may be a concave-convex surface formed by unevenness.

The MEMS sensor 1 includes a fixed structure 16 and a movable structure 17 that is displaced with respect to the fixed structure 16. For clarity, the fixed structure 16 is shown by hatching (first hatching) whose width is comparatively wider, and the movable structure 17 is shown by hatching (second hatching) whose width is comparatively narrower than the first hatching in FIG. 1.

The fixed structure 16 includes a frame portion 18 and a first cantilever structure 19.

The frame portion 18 has a layered structure consisting of the first layer 5 and the second layer 6, and defines the cavity 11 of the MEMS sensor 1. The first cantilever structure 19 includes a base end portion 20 connected to the frame portion 18 and an extension portion 21 that extends from the base end portion 20 in a floating state with respect to the cavity 11. The first cantilever structure 19 is supported in a cantilever manner by means of the frame portion 18.

Referring to FIG. 1, the frame portion 18 includes an outer frame 22 and an extension frame 23. The outer frame 22 forms the external shape of the MEMS sensor 1, for example. The outer frame 22 is formed in a quadrangular annular shape in a plan view. The cavity 11 is defined in an inner region of the outer frame 22. In this preferred embodiment, the outer frame 22 includes a pair of first side portions 24 that extend along the first direction X and that face each other in the second direction Y and a pair of second side portions 25 that extend along the second direction Y and that face each other in the first direction X.

The extension frame 23 is connected to an inner peripheral portion 26 of the outer frame 22. The extension frame 23 extends from the inner peripheral portion 26 of the outer frame 22 to the inner region of the outer frame 22. The extension frame 23 may be shaped like a plurality of bands formed mutually-independently. The extension frame 23 may have a width wider than the outer frame 22. The extension frame 23 may include a plurality of extension frames 23 that extend from parts, which face each other, of the inner peripheral portion 26 of the outer frame 22 and that have forward end portions 27 facing each other. The extension frame 23 may include a pair of extension frames 23 extending from parts of a pair of inner peripheral portions 26 of at least one of the pair of first side portions 24 and the pair of second side portions 25 of the outer frame 22. In this preferred embodiment, band-shaped extension frames 23 extend from two places of each one of the pair of second side portions 25, respectively, toward the second side portion 25 on the other side. Two extension frames 23 are formed at each of the second side portions 25, i.e., four extension frames 23 in total are formed at the second side portions 25.

Referring to FIG. 4, a forward end portion 27 of the extension frame 23 may have a removal portion 28 by which a part of the second layer 6 is selectively removed and by which the first principal surface 7 of the first layer 5 is exposed. In this preferred embodiment, the forward end portion 27 branches into a pair of branch portions 29, and a space portion between the pair of branch portions 29 may be the removal portion 28. In this case, the removal portion 28 may be a concave portion 30 that continuously has a first side surface 31 formed by one of the pair of branch portions 29, a second side surface 32 formed by the other one of the pair of branch portions 29, and a third side surface 33 formed by a connection portion 34 by which the pair of branch portions 29 are connected together. The concave portion 30 is surrounded from three directions of the first, second, and third side surfaces 31, 32, and 33, and the side opposite to the third side surface 33 is open. Referring to FIG. 5, the concave portion 30 is defined by the first and second layers 5 and 6 in a cross-sectional view. A bottom surface 36 of the concave portion 30 is formed by the first principal surface 7 of the first layer 5 that is continuous with a boundary surface 35 between the first layer 5 and the second layer 6. The first side surface 31, the second side surface 32, and the third side surface 33 of the concave portion 30 are formed by the second layer 6. Hence, the extension frame 23 is provided with a level difference based on a difference in height (thickness of the second layer 6) between the first principal surface 9 of the second layer 6 and the first principal surface 7 of the first layer 5. The bottom surface 36 of the concave portion 30 may be referred to as a stepped surface 37.

Referring to FIG. 4, the forward end portion 27 of the extension frame 23 may have a projection portion 38 (second projection portion) that selectively protrudes more forwardly than other parts of the forward end portion 27. In this preferred embodiment, the projection portion 38 may be formed of one of the extension portions of the pair of branch portions 29. Therefore, a level difference is formed between an end surface 39 of one of the pair of branch portions 29 and an end surface 40 of the other one of the pair of branch portions 29. The magnitude of this level difference corresponds to the length of the projection portion 38. Referring to FIG. 6, the projection portion 38 is formed by selectively projecting the second layer 6 that is one of the first and second layers 5 and 6. The projection portion 38 is connected integrally with the extension frame 23 in a floating state with respect to the cavity 11.

Referring to FIG. 1 and FIG. 2, the first cantilever structure 19 is formed of the second layer 6. The first cantilever structure 19 may include a plurality of first cantilever structures 19 that extend from the outer frame 22 in parallel with each other in the first direction X. In this preferred embodiment, six first cantilever structures 19 are connected to each of the second side portions 25 of the outer frame 22. The plurality of first cantilever structures 19 are formed between a pair of extension frames 23 adjoining each other in the second direction Y. The first cantilever structure 19 is an electrode fixed to the frame portion 18, and hence may be referred to as a fixed electrode 41.

The movable structure 17 is formed so that the entirety of the movable structure 17 is in a floating state with respect to the cavity 11. Referring to FIG. 1 and FIG. 2, the movable structure 17 is formed of the second layer 6. The movable structure 17 includes a main body portion 42 and a second cantilever structure 43.

The main body portion 42 faces the cavity 11 in the third direction Z that is a thickness direction of the semiconductor chip 2. The main body portion 42 is formed in a substantially quadrangular shape in a plan view. An open hole 44 that passes through the main body portion 42 in the thickness direction is formed in an inner region of the main body portion 42. The open hole 44 may be formed as a plurality of open holes 44. In this preferred embodiment, the plurality of open holes 44 are formed with a regular pattern in the inner region of the main body portion 42. The regular pattern may be formed in, for example, a matrix manner as shown in FIG. 1. Hence, the main body portion 42 may be formed in a grid-shaped manner.

A projection portion 46 that is an example of the extension portion is connected to the main body portion 42. Referring to FIG. 4, the projection portion 46 may be a projection portion 46 (first projection portion) that selectively protrudes from the main body portion 42 and that is housed in the concave portion 30 of the frame portion 18. In this preferred embodiment, the projection portion 46 protrudes outwardly from each of the four corner portions of the main body portion 42. The projection portion 46 may have a first side surface 47, a second side surface 48, and a third side surface 49 that face the first side surface 31, the second side surface 32, and the third side surface 33 of the concave portion 30 with intervals between the first, second, and third side surfaces 47, 48, 49 and the first, second, and third side surfaces 31, 32, 33, respectively. Referring to FIG. 5, the projection portion 46 is formed thinner than the main body portion 42. In this preferred embodiment, an upper surface 50 of the main body portion 42 and an upper surface 51 of the projection portion 46 are flatly continuous with each other. On the other hand, a level difference 54 is formed between a lower surface 52 of the main body portion 42 and a lower surface 53 of the projection portion 46. Hence, the projection portion 46 is formed thinner than the main body portion 42. More concretely, the lower surface 52 of the main body portion 42 is formed on an extension surface 45 of the boundary surface 35 between the first layer 5 and the second layer 6. On the other hand, the lower surface 53 of the projection portion 46 is formed on the first-principal-surface-3 side of the semiconductor chip 2 with respect to the boundary surface 35. The lower surface 53 of the projection portion 46 faces the stepped surface 37 of the concave portion 30 with an interval between the lower surface 53 and the stepped surface 37.

A loss portion 55 formed by partially losing a part of the main body portion 42 is formed at the main body portion 42. In this preferred embodiment, a part of an outer peripheral portion 56 forming an outer frame of the main body portion 42 having a grid shape is removed from an outer peripheral surface 57 of the main body portion 42 to the open hole 44 adjacent to the outer peripheral surface 57, and, as a result, the loss portion 55 is formed. Hence, the loss portion 55 is formed that is sandwiched between a pair of side surfaces 58 formed by the outer peripheral portion 56 of the main body portion 42 and that is open in the open hole 44 and the outer peripheral surface 57. The projection portion 38 of the fixed structure 16 is housed in the loss portion 55. The projection portion 38 has a side surface 59 facing the side surface 58 of the loss portion 55 at a distance from the side surface 58.

Referring to FIG. 1 and FIG. 2, the second cantilever structure 43 is formed of the second layer 6. The second cantilever structure 43 may include a plurality of second cantilever structures 43 that extend from the outer peripheral portion 56 of the main body portion 42 in parallel with each other in the first direction X. In this preferred embodiment, three second cantilever structures 43 and three second cantilever structures 43 are connected to the pair of outer peripheral portions 56, respectively, which face each other in the first direction X, of the main body portion 42. The plurality of second cantilever structures 43 are formed between the pair of loss portions adjoining each other in the second direction Y. The second cantilever structure 43 is an electrode supported by the main body portion 42 in a floating state with respect to the cavity 11, and hence may be referred to as a movable electrode 60.

Referring to FIG. 3, the second cantilever structure 43 includes a first isolation coupling portion 61. The first isolation coupling portion 61 has an end portion 62 that extends from the first principal surface 3 of the semiconductor chip 2 (the first principal surface 9 of the second layer 6) to the cavity 11 and that is exposed in the cavity 11. The end portion 62 of the first isolation coupling portion 61 may have an end surface 63 that is substantially flush with the second principal surface 10 of the second layer 6. The first isolation coupling portion 61 is made of an insulation film. In this preferred embodiment, the first isolation coupling portion 61 is made of SiO₂. The first isolation coupling portion 61 electrically isolates at least one part or all of the second cantilever structure 43. A part or all of the second cantilever structure 43 is physically separated from other components forming the movable structure 17 by means of the first isolation coupling portion 61. In this preferred embodiment, the first isolation coupling portion 61 is formed at a base end portion of each of the second cantilever structures 43.

As thus described, the first cantilever structure 19 and the second cantilever structure 43 are each formed in a comb-teeth shape, and mesh with each other with an interval therebetween. The first cantilever structure 19 and the second cantilever structure 43 face each other in the second direction Y. For example, a plurality of capacitor units each of which consists of the single second cantilever structure 43 and the pair of first cantilever structures 19 between which the second cantilever structure 43 is sandwiched from both sides may be formed as shown in FIG. 1.

The movable structure 17 is displaceably connected to the fixed structure 16 through a flexible connection structure 64. The flexible connection structure 64 is formed by use of the second layer 6 in the same way as the movable structure 17. For example, the flexible connection structure 64 may be an elastic structure (spring structure) that is extensible and contractible in the second direction Y (direction in which the first cantilever structure 19 and the second cantilever structure 43 face each other). In this preferred embodiment, the flexible connection structure 64 is connected to the outer frame 22 of the fixed structure 16 through a connection portion 65.

When the MEMS sensor 1 receives acceleration in the second direction Y, the flexible connection structure 64 connected to the movable structure 17 expands and contracts in the second direction Y. The movement distance of the flexible connection structure 64 at this time is detected as a change in the electrostatic capacity between the fixed electrode 41 and the movable electrode 60, and is taken out as an electric signal corresponding to the acceleration in the second direction Y. Next, a method for manufacturing the MEMS sensor 1 will be described.

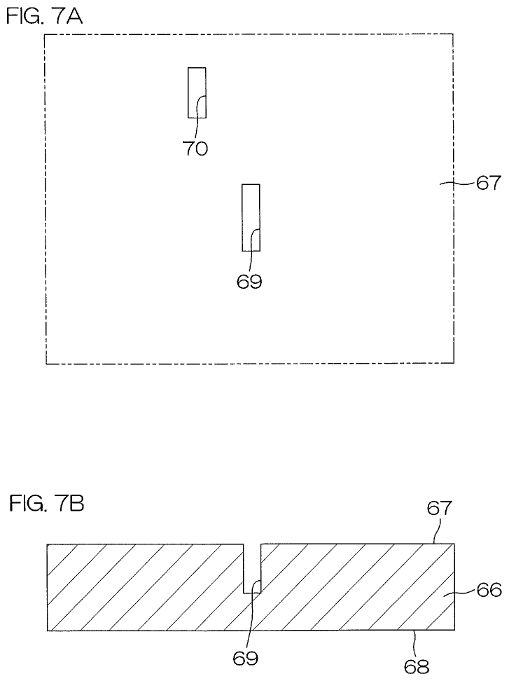

FIGS. 7A, 7B to FIGS. 11A, 11B are views each of which shows a part of a process for manufacturing the MEMS sensor 1. In FIGS. 7A, 7B to FIGS. 11A, 11B, the drawings to which “A” is affixed are plan views corresponding to FIG. 4, and the drawings to which “B” is affixed are cross-sectional views corresponding to FIG. 5.

For example, referring to FIG. 7A and FIG. 7B, a semiconductor wafer 66 that forms the first layer 5 of the MEMS sensor 1 is prepared in order to manufacture the MEMS sensor 1. The semiconductor wafer 66 has a first wafer principal surface 67 and a second wafer principal surface 68 on the side opposite to the first wafer principal surface 67. The first wafer principal surface 67 is the first principal surface 7 of the first layer 5, and the second wafer principal surface 68 is the second principal surface 8 of the first layer 5 (the second principal surface 4 of the semiconductor chip 2). In this preferred embodiment, the semiconductor wafer 66 is a Si wafer. Thereafter, referring to FIG. 7A and FIG. 7B, the semiconductor wafer 66 is selectively etched from the first wafer principal surface 67, and, as a result, a first trench 69 and a second trench 70 are formed. The first trench 69 and the second trench 70 may be formed by, for example, anisotropic deep RIE (Reactive Ion Etching).

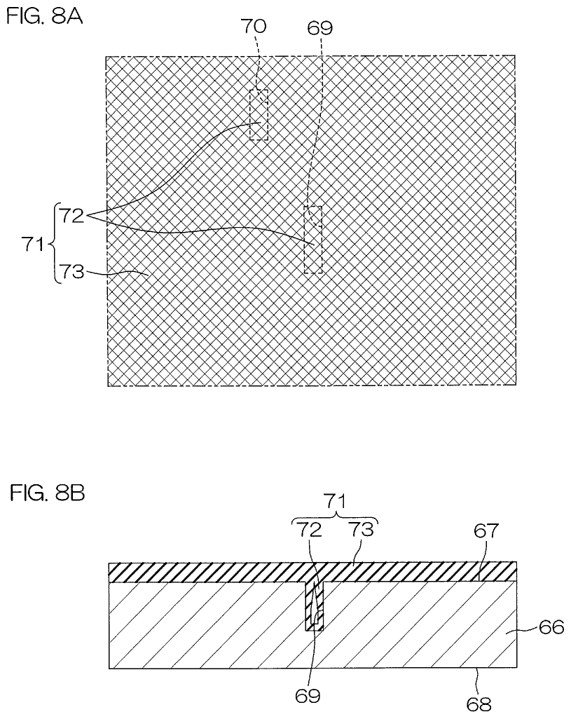

Thereafter, referring to FIG. 8A and FIG. 8B, a sacrifice layer 71 is formed on an inner surface of the first trench 69 and on the first wafer principal surface 67 of the semiconductor wafer 66. The sacrifice layer 71 is formed by, for example, thermal oxidation. The sacrifice layer 71 is made of a material different from that of the semiconductor wafer 66, and may be made of an insulation material having an etching selection ratio with respect to a first semiconductor material making the semiconductor wafer 66. In this preferred embodiment, the semiconductor wafer 66 is Si, and the sacrifice layer 71 is SiO₂. The sacrifice layer 71 integrally includes a first part 72 buried in the first trench 69 and in the second trench 70 and a second part 73 with which the first wafer principal surface 67 of the semiconductor wafer 66 is covered.

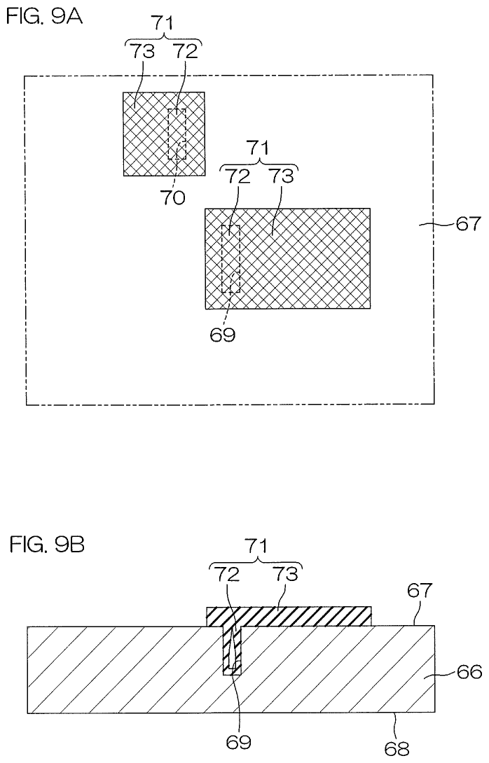

Thereafter, referring to FIG. 9A and FIG. 9B, the second part 73 of the sacrifice layer 71 is selectively removed. More concretely, parts other than the concave portion 30 of the fixed structure 16 and the loss portion 55 of the movable structure 17 are removed so as to leave a pattern corresponding to the concave portion 30 of the fixed structure 16 and a pattern corresponding to the loss portion of the movable structure 17. Hence, the second part 73 of the sacrifice layer 71 takes a form in which the second part 73 of the sacrifice layer 71 has been selectively led out from the first part 72 of the sacrifice layer 71 along the first wafer principal surface 67 of the semiconductor wafer 66. The first wafer principal surface 67 of the semiconductor wafer 66 is exposed in a region from which the second part 73 of the sacrifice layer 71 has been removed.

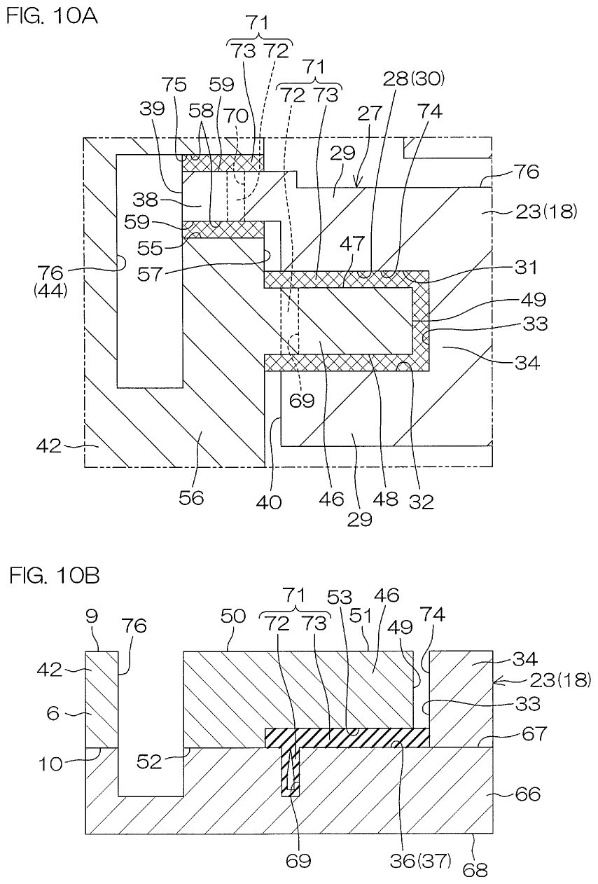

Thereafter, referring to FIG. 10A and FIG. 10B, the second layer 6 is formed at the first wafer principal surface 67 of the semiconductor wafer 66 so as to cover the sacrifice layer 71. The second layer 6 is formed on the semiconductor wafer 66 by, for example, epitaxial growth. In this preferred embodiment, the second layer 6 is made of the first semiconductor material (for example, Si) that is the same as the semiconductor wafer 66.

Thereafter, referring to FIG. 10A and FIG. 10B, a third trench 74, a fourth trench 75, and a fifth trench 76 are formed by etching from the first principal surface 9 of the second layer 6. In this preferred embodiment, the third trench 74 and the fourth trench 75 that are to expose the sacrifice layer 71 and the fifth trench 76 that is to form the cavity 11 are formed. The third trench 74, the fourth trench 75, and the fifth trench 76 may be simultaneously formed, or may be formed through separate steps. The third trench 74, the fourth trench 75, and the fifth trench 76 may be formed by, for example, anisotropic deep RIE (Reactive Ion Etching).

In this preferred embodiment, the third trench 74 is formed by etching the second layer 6 with a pattern corresponding to a gap between the concave portion 30 of the fixed structure 16 and the projection portion 46 of the movable structure 17. Hence, the first part 72 of the sacrifice layer 71 is covered with the projection portion 46 of the movable structure 17, whereas the second part 73 of the sacrifice layer 71 is exposed from the third trench 74. A part (in this preferred embodiment, peripheral edge portion) of the second part 73 of the sacrifice layer 71 may be selectively exposed from the third trench 74 as shown in FIG. 10A. The fourth trench 75 is formed by etching the second layer 6 with a pattern corresponding to a gap between the loss portion 55 of the movable structure 17 and the projection portion 38 of the fixed structure 16. Hence, the first part 72 of the sacrifice layer 71 is covered with the projection portion 38 of the fixed structure 16. On the other hand, the second part 73 of the sacrifice layer 71 is exposed from the fourth trench 75. A part (in this preferred embodiment, peripheral edge portion) of the second part 73 of the sacrifice layer 71 may be selectively exposed from the fourth trench 75 as shown in FIG. 10A.

The fifth trench 76 is formed by etching the second layer 6 and the first layer 5 with a pattern corresponding to a gap between the fixed structure 16 and the movable structure 17 (for example, a gap between the first cantilever structure 19 and the second cantilever structure 43) excluding the open hole 44 of the movable structure 17, the third trench 74, and the fourth trench 75. In other words, the fifth trench 76 has a bottom portion that passes through the second layer 6 and that reaches the first layer 5.

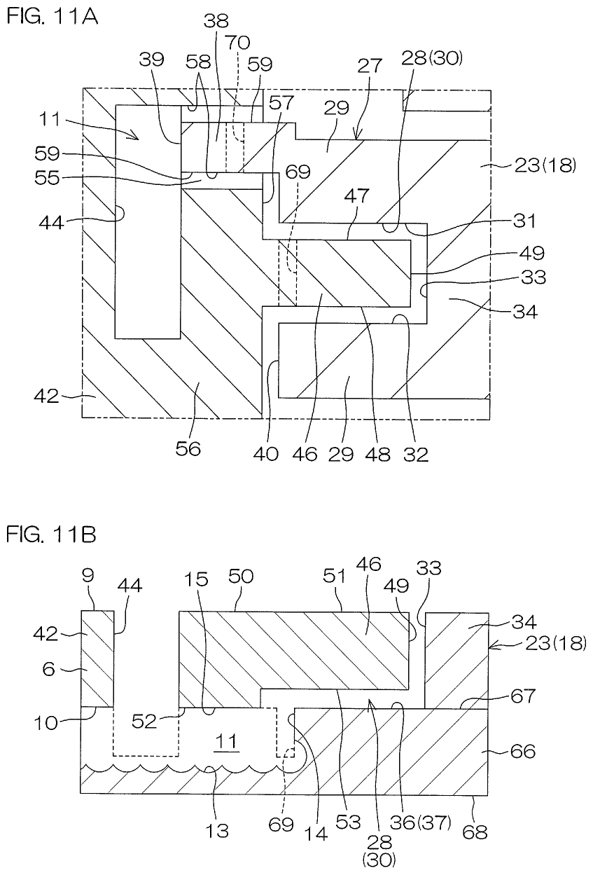

Thereafter, referring to FIG. 11A and FIG. 11B, the cavity 11 is formed in the semiconductor wafer 66 by isotropically etching the semiconductor wafer 66 through the fifth trench 76. The etching operation progresses in the lateral direction along the first wafer principal surface 67 of the semiconductor wafer 66, and therefore the cavity 11 reaches the first and second trenches 69 and 70, and is united integrally with these trenches. Hence, the first and second trenches 69 and 70 become part the cavity 11.

Thereafter, referring to FIG. 11A and FIG. 11B, the sacrifice layer 71 is etched through the third trench 74 and the fourth trench 75. For example, a fluorine-based gas (for example, HF) is used as an etching gas. Hence, the sacrifice layer 71 is removed, and, as a result, a gap is formed between the lower surface 53 of the projection portion 46 of the movable structure 17 and the stepped surface 37 of the fixed structure 16. Thereafter, the semiconductor wafer 66 is divided into chip units, and, as a result, the MEMS sensor 1 is obtained.

As described above, with the MEMS sensor 1, the lower surface 53 of the projection portion 46 of the movable structure 17 faces the stepped surface 37 of the concave portion 30 of the fixed structure 16 with an interval therebetween in the third direction Z. The projection portion 46 comes into contact with the stepped surface 37 when the movable structure 17 is excessively displaced in the third direction Z toward the cavity 11, hence making it possible to restrict the movable structure 17 from being excessively displaced downwardly. As a result, it is possible to protect the MEMS structure.

Additionally, the projection portion 46 of the movable structure 17 is interposed between the first side surface 31 and the second side surface 32 of the concave portion 30 at a distance from the first and second side surfaces 31 and 32 in the second direction Y. When the movable structure 17 is excessively displaced in the second direction Y, the projection portion 46 comes into contact with the first and second side surfaces 31 and 32 of the concave portion 30, hence making it possible to restrict the movable structure 17 from being excessively displaced in the second direction Y. As a result, it is possible to prevent contact between the first cantilever structure 19 and the second cantilever structure 43, hence making it possible to protect the MEMS structure.

Additionally, the projection portion 38 of the fixed structure 16 is interposed between the side surfaces 58 of the loss portion 55 of the movable electrode 60 at a distance from the side surfaces 58 in the second direction Y. When the movable structure 17 is excessively displaced in the second direction Y, the projection portion 38 comes into contact with the side surface 58 of the loss portion 55, and therefore it is possible to restrict the movable structure 17 from being excessively displaced in the second direction Y. As a result, it is possible to prevent contact between the first cantilever structure 19 and the second cantilever structure 43, hence making it possible to protect the MEMS structure.

The preferred embodiments of the present disclosure have been described as above, and yet the present disclosure can be carried out in other modes.

For example, the present disclosure can be applied to a structure that detects acceleration that acts in the first and third directions X and Z although acceleration that acts in the second direction Y is detected among the first, second, and third directions X, Y, and Z of the MEMS sensor 1 as mentioned in the above-described preferred embodiment. For example, if a structure achieved by rotating the structure shown in FIG. 1 by 90° is employed, the first cantilever structure 19 and the second cantilever structure 43 face each other in the first direction X, and therefore it is possible to detect acceleration that acts in the first direction X.

Additionally, the present disclosure can be applied to other MEMS sensors although the acceleration sensor has been employed as an example of a MEMS sensor in the above-described preferred embodiment. For example, a gyro sensor, a pressure sensor, etc. can be mentioned as that type MEMS sensor.

Additionally, although the semiconductor chip is formed to have a layered structure consisting of first and second layers in the above-described preferred embodiment, the layered structure may consist of three or more layers.

Besides, various design changes can be made within the scope of the subject matters recited in the appended claims.

1. A MEMS sensor comprising:
a semiconductor chip that has a first principal surface and a second principal surface on a side opposite to the first principal surface and that has a cavity formed in an inside of the semiconductor chip;
a frame portion that is formed on the side of the second principal surface of the semiconductor chip and that forms a bottom portion and a side portion of the cavity; and
a movable portion that is formed on the side of the first principal surface of the semiconductor chip and that is supported by the frame portion in a floating state with respect to the cavity,
wherein the frame portion has a stepped surface formed at a height position between the bottom portion of the cavity and the first principal surface, and
the movable portion includes a main body portion facing the cavity in a first direction that is a thickness direction of the semiconductor chip and an extension portion that extends from the main body portion toward an upper region of the stepped surface in a second direction perpendicular to the first direction and that faces the stepped surface in the first direction.

2. The MEMS sensor according to claim 1, wherein the frame portion has a concave portion that has a bottom surface formed of the stepped surface and a side surface extending from the bottom surface toward the first principal surface and that is open toward the side of the main body portion of the movable portion, and
the extension portion includes a first projection portion that is housed in the concave portion while selectively protruding from the main body portion and that has a side surface facing the side surface of the concave portion at a distance from the side surface of the concave portion.

3. The MEMS sensor according to claim 1, wherein the main body portion of the movable portion includes a loss portion formed by partially losing the main body portion, and
the frame portion includes a second projection portion that is housed in the loss portion while selectively protruding toward the loss portion and that has a side surface facing a side surface of the loss portion at a distance from the side surface of the loss portion.

4. The MEMS sensor according to claim 1, wherein the extension portion of the movable portion is formed thinner than the main body portion of the movable portion.

5. The MEMS sensor according to claim 1, wherein the semiconductor chip includes a first layer made of a first semiconductor material and a second layer that is formed on the first layer and that is made of a second semiconductor material, and
the stepped surface of the frame portion is formed by an upper surface of the first layer that is continuous with a boundary surface between the first layer and the second layer, and
the movable portion is formed by the second layer, and
the extension portion of the movable portion is formed thinner than the main body portion of the movable portion, and faces the stepped surface at a distance from the stepped surface.

6. The MEMS sensor according to claim 5, wherein the first semiconductor material and the second semiconductor material are materials that are the same as each other.

7. The MEMS sensor according to claim 1, further comprising a fixed electrode having a cantilever structure formed integrally with the frame portion,
wherein the movable portion includes a movable electrode that has a cantilever structure extending from the main body portion in parallel with the fixed electrode and that is displaced with respect to the fixed electrode.

8. The MEMS sensor according to claim 1, including an acceleration sensor.

9. A method for manufacturing a MEMS sensor, the method comprising:
a step of selectively forming a first trench in a first layer made of a first semiconductor material;
a step of selectively forming a sacrifice layer on the first layer, the sacrifice layer integrally including a first part that is made of a material having an etching selection ratio with respect to the first semiconductor material and that is buried in the first trench and a second part led out from the first part along a principal surface of the first layer;
a step of forming a second layer made of a second semiconductor material on the first layer so as to cover the sacrifice layer;
a step of forming a second trench in the second layer by selectively removing the second layer so that the first part of the sacrifice layer is covered with the second layer and so that the second part of the sacrifice layer is exposed from the second layer;
a step of forming a third trench that reaches the first layer from a principal surface of the second layer through the second layer;
a step of forming a cavity reaching the first trench in the first layer by isotropically etching the first layer through the third trench; and
a step of removing the sacrifice layer through the second trench.

10. The method for manufacturing a MEMS sensor according to claim 9, wherein the first semiconductor material is Si, and the sacrifice layer is SiO₂.

11. The method for manufacturing a MEMS sensor according to claim 9, wherein the step of forming the second trench and the step of forming the third trench are performed by a same etching step.
